(19) United States
(12) Patent Application Publication
(10) Pub. No.: US 2010/0235692 A1
(43) Pub. Date: Sep. 16, 2010

(54) MEMORY TEST CIRCUIT AND PROCESSOR

(75) Inventor: Seiji MURATA, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/695,358

(22) Filed: Jan. 28, 2010

(30) Foreign Application Priority Data
Mar. 10, 2009 (JP) 2009-057026

(51) Int. Cl. G11C 29/08; G06F 11/26

(52) U.S. Cl. 714/718; 714/E11.159

(57) ABSTRACT

A memory test circuit for testing a memory including a first circuit for performing a logic operation of a test signal, which determines whether the memory is operated in a test mode or in an ordinary operation mode, and an expected value representing a value which is expected to be set to data read from the memory, and a second circuit for outputting an exclusive OR of an output signal from the first circuit and the data read from the memory.

### CROSS-REFERENCE TO RELATED APPLICATIONS

This application is based upon and claims the benefit of priority of the prior Japanese Patent Application No. 2009-57026, filed on Mar. 10, 2009, the entire contents of which are incorporated herein by reference.

### FIELD

The embodiments discussed herein are related to a memory test circuit and a processor.

### BACKGROUND

A built-in self test (BIST) system is used for a memory test. In the BIST, a memory test is executed by creating a test pattern, reading and writing data from and to a memory to be tested according to the created test pattern, and evaluating a value read from the memory and an expected value.

When the BIST is executed, a circuit is provided to compare a value output from a memory based on an operation pattern output from a test pattern creation circuit with an expected value output from the test pattern creation circuit. Accordingly, there is proposed a memory test device for providing a circuit, which compares an output from a memory with an expected value output from a test pattern creation circuit, with a path different from a memory output path used when an ordinary memory is used. For example, Japanese Patent Application Laid-Open Publication No. 2004-30783 is exemplified as a technique for executing the BIST.

An expected value comparator for a memory test has a plurality of logic gates. Accordingly, when the expected value comparator is disposed independently of the ordinary memory output path, since a signal passing through the expected value comparator passes through a path having logic gates more than those of an ordinary memory output, the signal passing through the expected value comparator is more delayed than a signal ordinarily output from the memory. Further, since an ordinary clock frequency is not set based on a path passing through the expected value comparator, when a memory passing through the expected value comparator is tested using the ordinary clock frequency, a malfunction occurs. Accordingly, a clock frequency in a test is set lower than the ordinary clock frequency in consideration of a delay of a signal in the expected value comparator. However, a memory test executed using the clock frequency lower than the ordinary clock frequency cannot be applied to a test of an operation of an ordinarily operating memory because the memory is not tested by the ordinary clock frequency.

### SUMMARY

A memory test circuit for testing a memory including a first circuit for performing a logic operation of a test signal, which determines whether the memory is operated in a test mode or in an ordinary operation mode, and an expected value representing a value which is expected to be set to data read from the memory, and a second circuit for outputting an exclusive OR of an output signal from the first circuit and the data read from the memory.

The object and advantages of the various embodiments will be realized and attained by means of the elements and combinations particularly pointed out in the claims.

It is to be understood that both the foregoing general description and the following detailed description are exemplary and explanatory and are not restrictive of the various embodiments, as claimed.

### BRIEF DESCRIPTION OF DRAWINGS

FIG. 1 illustrates an example of a processor including a memory test circuit;

FIG. 2 illustrates an example of a memory test circuit 20;

FIG. 3 illustrates an example of a first logic circuit 21;

FIG. 4 illustrates an example of a second logic circuit 22;

FIG. 5A illustrates an example of a combination table of a test signal test, read data mout, and an expected value EXPD;

FIG. 5B illustrates an example of a table obtained by rearranging the table illustrated in FIG. 5A to determine a verification value by a logic operation;

FIG. 6A illustrates a first embodiment of a memory test circuit using a NAND circuit;

FIG. 6B illustrates an example of a NAND circuit 22a-4 or 22a-5;

FIG. 7A is a timing chart of signals flowing to a memory test circuit 20a in a test mode;

FIG. 7B is a timing chart of signals flowing to the memory test circuit 20a in an ordinary operation mode;

FIG. 8 illustrates a second embodiment of the memory test circuit using transfer gate circuits;

FIG. 9A is a timing chart of signals flowing to a memory test circuit 20b in the test mode;

FIG. 9B is a timing chart of signals flowing to the memory test circuit 20b in the ordinary operation mode;

FIG. 10 illustrates a third embodiment of the memory test circuit using transfer gate circuits;

FIG. 11A is a timing chart of signals flowing to a memory test circuit 20c in the test mode; and

FIG. 11B is a timing chart of signals flowing to the memory test circuit 20c in the ordinary operation mode.

### DESCRIPTION OF EMBODIMENTS

An embodiment of a processor including a memory test circuit will be explained below referring to the drawings.

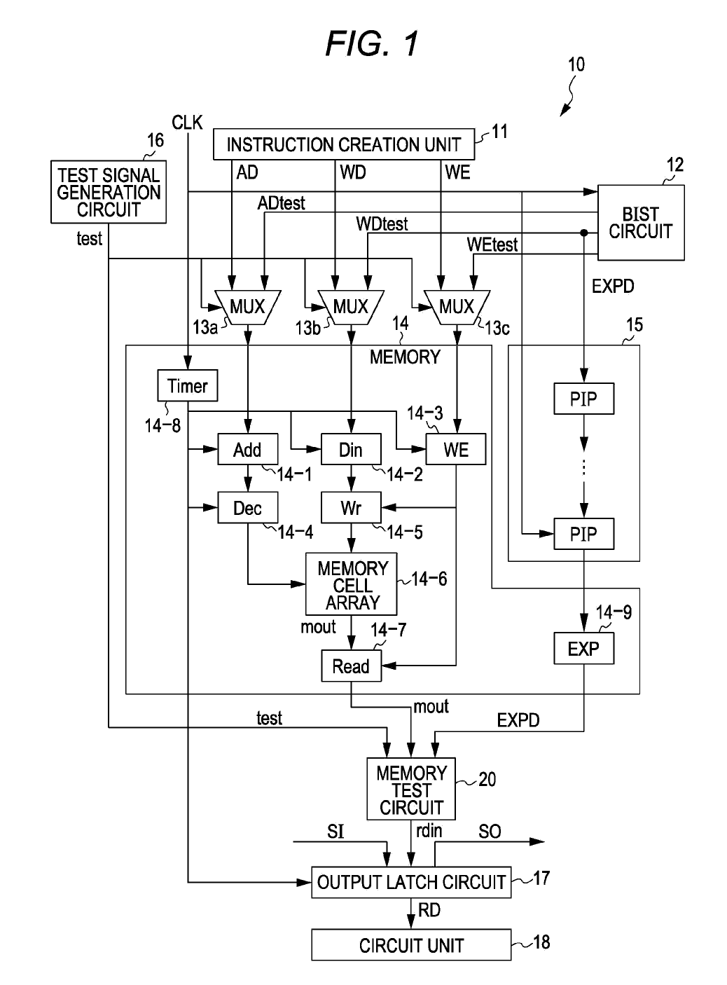

FIG. 1 illustrates an example of a processor according to an embodiment including the memory test circuit. As illustrated in FIG. 1, a processor 10 including the memory test circuit according to the embodiment has an instruction creation unit 11, a test pattern creation circuit 12, multiplexers (MUX) 13a to 13c, a memory 14, a pipe latch circuit unit (PIP) 15, a test signal generation circuit 16, and a memory test circuit 20. As illustrated in FIG. 1, the processor 10 may have an output latch circuit 17 and a circuit unit 18 in a rear stage of the memory test circuit 20. The respective components of the processor 10 will be explained below.

The instruction creation unit 11 is a device for executing arithmetic processings such as four arithmetical operations and a logic operation. The instruction creation unit 11 reads an instruction from a main memory disposed externally of the processor 10 and executes the instruction to thereby execute the various calculations and controls. The instruction creation unit 11 outputs signals AD, WD, WE to the memory 14. Note that AD denotes an address data signal, WD denotes a write data signal, and WE denotes a “write enable signal”.

CLK illustrated in FIG. 1 denotes a system clock signal generated by a clock generator externally of the processor 10. EXPD illustrated in FIG. 1 denotes an expected value of data output from a memory cell array 14-6 to be described later.

The test pattern creation circuit 12 receives the system clock signal CLK and creates a test pattern synchronized with the system clock signal CLK. The test pattern includes an address data signal ADtest, a write data signal WDtest, and a write permission signal WEtest. An example of the test pattern will be described later together with explanation of the memory 14.

The test pattern creation circuit 12 outputs the address data signal ADtest for test to the multiplexer 13a.

The test pattern creation circuit 12 outputs the write data signal WDtest for test to the multiplexer 13b. The test pattern creation circuit 12 outputs the write permission signal WEtest for test to the multiplexer 13c. The test pattern creation circuit 12 outputs the write data signal WDtest to the pipe latch circuit unit 15 as the expected value EXPD.

A symbol test illustrated in FIG. 1 denotes a test signal. The test signal test takes any value of a logic value representing that the memory is operated in a test mode and a logic value representing that the memory is operated in an ordinary operation mode.

Note that the test signal generation circuit 16 outputs test signal test of the logic value representing that the test is executed or the logic value representing that the test is not executed according to a value of a control register (not illustrated) in the processor 10.

The multiplexers 13a to 13c are circuits for selecting one signal from a plurality of input signals according to the test signal test, and outputting the selected signal. In other words, when the multiplexers 13a to 13c receive the test signal test which determines that the memory is operated in the test mode, the multiplexers 13a to 13c each select a signal for test output from the test pattern creation circuit 12 and outputs the selected signal. When the multiplexers 13a to 13c receive the test signal test which determines that the memory is operated in the ordinary operation mode, the multiplexers 13a to 13c select a signal for test output from the instruction creation unit 11 and output the selected signal.

The multiplexer 13a receives the address data signal AD output from the instruction creation unit 11 or the address data signal ADtest for test output from the test pattern creation circuit 12, and outputs either of the address data signals according to the test signal test.

The multiplexer 13b receives the write data signal WD output from the instruction creation unit 11 or the write data signal WDtest for test output from the test pattern creation circuit 12, and outputs either of the write data signals according to the test signal test.

The multiplexer 13c receives the write permission signal WE output from the instruction creation unit 11 or the write permission signal WEtest for test output from the test pattern creation circuit 12, and outputs either of the write permission signals according to the test signal test.

The memory 14 is a high-speed and small-capacity memory used to compensate a difference between an arithmetic operation speed of the instruction creation unit 11 and a data read speed for reading data from the main memory by holding a part of the data stored in the main memory. Although the memory 14 may be a dynamic random access memory (DRAM), it is preferably a static random access memory (SRAM), which can operate faster than the DRAM.

The memory 14 illustrated in FIG. 1 has an address latch circuit (Add) 14-1, a write data signal latch circuit (Din) 14-2, a write permission signal latch circuit (WE) 14-3, a decoder circuit (Dec) 14-4, a write circuit (Wr) 14-5, and a memory cell array 14-6. Further, the memory 14 has a read circuit (Read) 14-7, a timer 14-8, and an expected value latch circuit (EXP) 14-9.

The address latch circuit 14-1 latches the address data signal, the write data signal latch circuit 14-21 latches the write data signal, and the write permission signal latch circuit 14-3 latches the write permission signal, respectively. The decoder circuit 14-4 decodes the address stored in the address latch circuit 14-1. The write circuit 14-5 writes the write data signal to a memory cell of the address which is decoded by the decoder circuit 14-4 during a period in which the write permission signal from the write permission signal latch circuit 14-3 is asserted. The read circuit 14-7 reads data from the memory cell of the address decoded by the decoder circuit 14-4 during a period in which the write permission signal from the write permission signal latch circuit 14-3 is negated. The timer 14-8 obtains the system clock signal CLK and transfers the obtained system clock signal CLK to respective circuits. The read circuit 14-7 is a circuit for receiving the read data mout transferred from the memory cell array 14-6 and outputs the received read data mout to the memory test circuit 20. The expected value latch circuit 14-9 is a latch circuit for storing the expected value EXPD which is output from the test pattern creation circuit 12 through the pipe latch circuit unit 15.

An example of a test pattern created by the test pattern creation circuit 12 will be explained. The test pattern exemplified below has three steps.

At a first step, an operation for writing the write data signal WDtest for test to the memory cell array 14-6 is executed. The decoder circuit 14-4 applies a voltage to an address line of the memory cell array 14-6 designated by the address data signal ADtest for test. The write circuit 14-5 writes the write data signal WDtest “0” to a cell designated by the address line during a period in which the write permission signal is asserted. The write operation of the write data signal WDtest “0” for test is executed to all the memory cells to in an ascending order or in a descending order of addresses.

At a second step, an operation for reading a data signal “0” from the memory cells in the ascending order of the addresses as well as an operation for writing a data signal “1” to the same memory cells are executed. The decoder circuit 14-4 applies a voltage to the address line of the memory cell array 14-6 designated by the address data signal ADtest for test. The write circuit 14-5 reads the data signal “0” from the cell designated by the address line during a period in which the write permission signal is negated. The data signal write operation at the second step executes the same operation as the write operation explained at the first step as to the write data signal WDtest “1”.

At a third step, an operation for reading the data signal “1” from the memory cell in the descending order of the addresses as well as an operation for writing the data signal “0” to the same memory cell are executed. As to the data signal read operation, the same read operation as that explained in the second step is executed. The data signal write operation is the same as that explained at the first step.

Since the test pattern creation circuit 12 creates the test pattern as described above, the memory test circuit 20 can not only read and write “0” and “1” once to the respective cells of the memory cell array 14-6 but also can change an address order and read/write timing and execute a memory test. The test pattern allows the memory test circuit 20 to execute a test to any of memory cells to discover a faultily wired address line and data line, a failure of write or read operation, and the like.

The memory test circuit 20 outputs the exclusive OR of the read data mout and the AND result of the test signal test and the expected value EXPD to the output latch circuit 17 as rdin. The memory test circuit 20 outputs the read data mout while a test is not executed. When a test is executed, the memory test circuit 20 outputs an agreement verification value of the expected value EXPD and the read data mout. When the expected value EXPD agrees with the read data mout, the agreement verification value is a positive logic, and when the expected value EXPD disagrees with the read data mout, the agreement verification value is a negative logic. The memory test circuit 20 will be described later in detail.

The pipe latch circuit unit 15 has a plurality of pipe latch circuits. Each pipe latch circuit has a function for storing the expected value EXPD output from the test pattern creation circuit 12, and sequentially outputs the stored expected value EXPD to a pipe latch circuit of a next stage in synchronization with the system clock signal CLK. The pipe latch circuit unit 15 has the pipe latch circuits equal to the number of stages of the circuit in the memory 14 so that the read data mout output from the memory 14, and the expected value EXPD output from the test pattern creation circuit 12 are output to the memory test circuit 20 in synchronization with each other.

The output latch circuit 17 is a circuit for shifting scan data input from a scan-in SI in response to the scan clock signal SCLK from the timer 14-8, and sequentially outputs the shifted scan data from a scan-out SO. The output latch circuit 17 is mounted on the processor 10 as a part of a scan chain.

The circuit unit 18 makes use of read data RD output from the memory test circuit 20 through the output latch circuit 17. The circuit unit 18 is for example, a combination logic circuit for storing, for example, the read data to a register of the instruction creation unit 11.

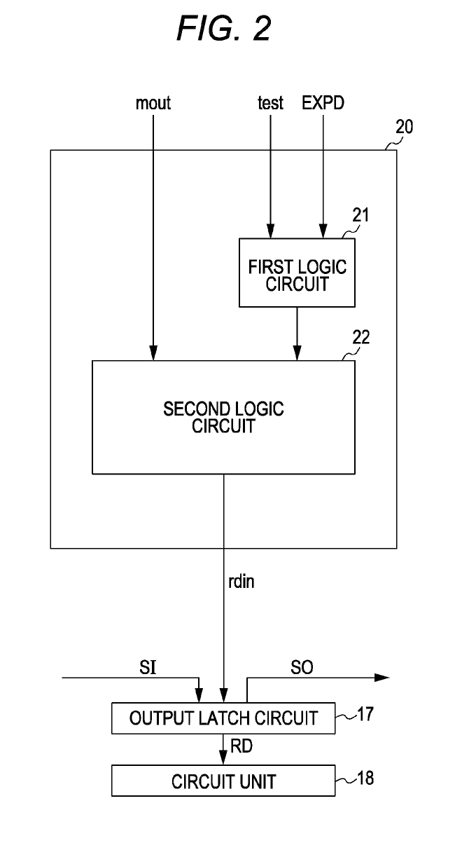

FIG. 2 is a view illustrating an example of the memory test circuit 20. The memory test circuit 20 has a first logic circuit 21 and a second logic circuit 22. The respective circuits will be explained below.

The first logic circuit 21 receives the test signal test and the expected value EXPD, and executes a logical operation of the test signal test and the expected value EXPD. The first logic circuit 21 receives, for example, the test signal test and the expected value EXPD, and executes AND operation of the test signal test with the expected value EXPD.

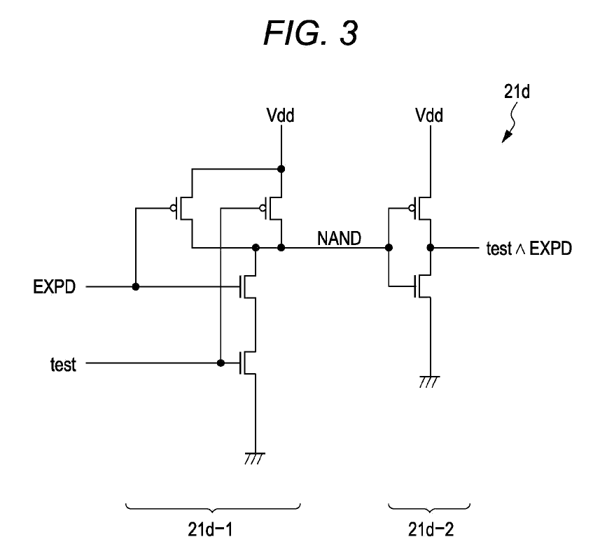

FIG. 3 illustrates an example of the first logic circuit. A first logic circuit 21d, as an example of the first logic circuit 21, illustrated in FIG. 3 has a NAND circuit 21d-1 and an inverter circuit 21d-1. As illustrated in FIG. 3, the NAND circuit 21d-1 and the inverter circuit 21d-1 use a complementary metal oxide semiconductor (CMOS).

The NAND circuit 21d-1 receives the test signal test and the expected value EXPD, and outputs NAND result which is a negative AND of the test signal test and the expected value EXPD.

The inverter circuit 21d-1 receives the NAND of the test signal test and the expected value EXPD, and inverts the NAND result to thereby output an AND signal testΛEXPD of the test signal test and the expected value EXPD.

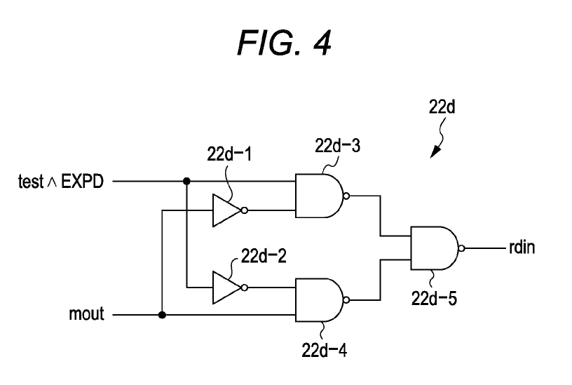

FIG. 4 illustrates an example of the second logic circuit. A second logic circuit 22d, as an example of the second logic circuit 22, illustrated in FIG. 4 has inverter circuits 22d-1 and 22d-2 and NAND circuits 22d-3, 22d-4, and 22d-5. Note that, although the inverter circuits 22d-1, 22d-2 illustrated in FIG. 4 have the same circuit arrangement as that of the inverter circuit 21d-1 illustrated in FIG. 3, the inverter circuits are simply illustrated by MIL logic symbols in FIG. 4 for simplification. Further, although the NAND circuits 22d-3, 22d-4, and 22d-5 illustrated in FIG. 4 have the same circuit arrangement as that of the NAND circuit 21d-2 illustrated in FIG. 3, the NAND circuits 22d-3, 22d-4, and 22d-5 are simply illustrated by MIL logic symbols in FIG. 4.

The inverter circuit 22d-1 receives the read data mout, and outputs an inverted signal of the read data mout. The inverter circuit 22d-2 receives an AND signal testΛEXPD of the test signal test and the expected value EXPD, and outputs an inverted signal of the AND signal testΛEXPD.

The NAND circuit 22d-3 receives the inverted signal of the read data mout and the AND signal testΛEXPD, and outputs NAND result of the inverted signal of the read data mout and the AND signal testΛEXPD. The NAND circuit 22d-4 receives the inverted signal of the AND signal testΛEXPD and the read data mout, and outputs NAND of the inverted signal of the AND signal testΛEXPD and the read data mout.

The NAND circuit 22d-5 receives an output signal of the NAND circuit 22d-3 and an output signal of the NAND circuit 22d-4, and outputs NAND of the output signal of the NAND circuit 22d-3 and the output signal of the NAND circuit 22d-4. NAND result of the output signal of the NAND circuit 22d-3 and the output signal of the NAND circuit 22d-4 corresponds to the exclusive OR of the AND signal testΛEXPD and the read data mout.

Note that the second logic circuit 22d illustrated in FIG. 4 may use other logic circuit which executes the same logic operation as the second logic circuit 22 by De Morgan's laws. For example, the second logic circuit 22 may use an NOR circuit which inputs the output signal of the circuit 22d-3 and the output signal of the NAND circuit 22d-4 after they are inverted in place of the NAND circuit 22d-5.

As described above, the second logic circuit 22 receives the output signal and the read data mout of the first logic circuit 21, and outputs the exclusive OR of the output signal and the read data of the first logic circuit 21 to the output latch circuit 17. When the test signal test indicates the ordinary operation mode, the second logic circuit 22 outputs the read data, and when the test signal test indicates the test mode, the second logic circuit 22 outputs an agreement verification value of the expected value EXPD and the read data.

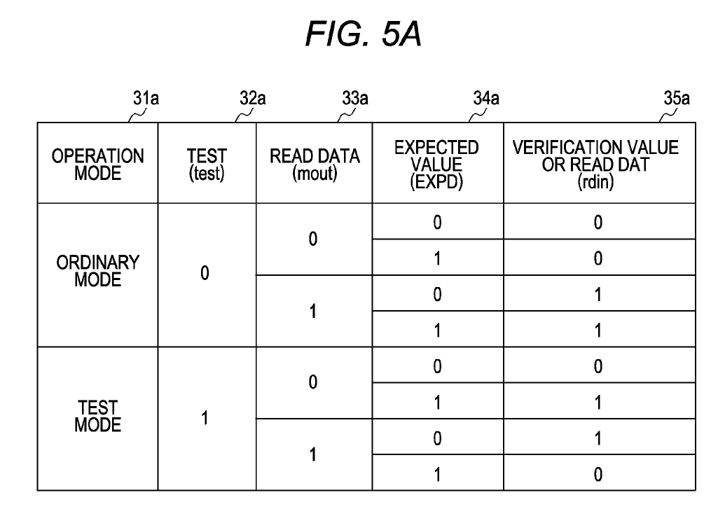

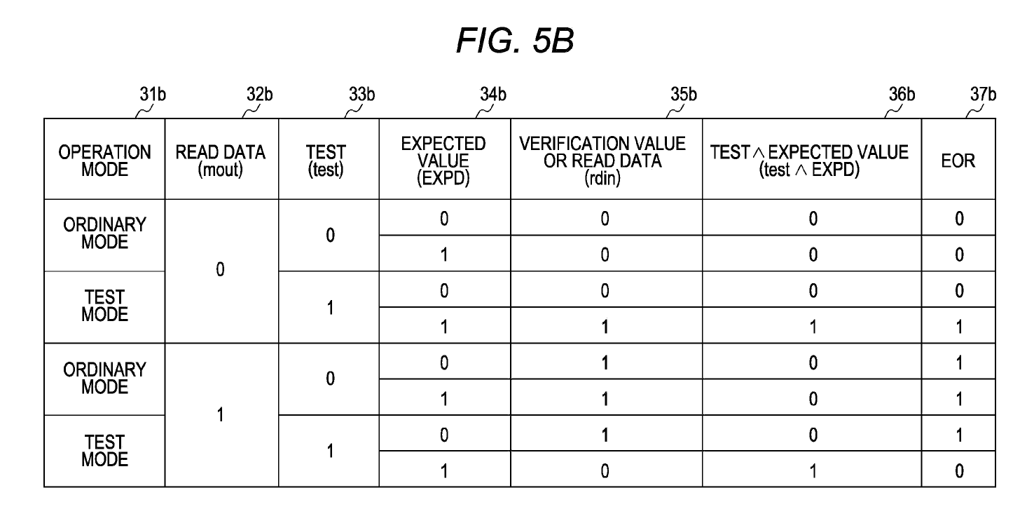

The logic operation executed by the first logic circuit 21 and the second logic circuit 22 as described above will be explained below using FIGS. 5A and 5B.

FIG. 5A is a view illustrating an example of a combination table of the test signal test, the read data mout, and the expected value EXPD. A column numeral 31a represents the operation mode of the memory 14. A column 32a represents a logic value of the test signal test. A column 33a represents a logic value of the read data mout. A column 34a represents a logic value of the expected value EXPD. A column 35a represents a verification value representing a result of verification verifying whether or not the read data mout agrees with the expected value EXPD in the test mode. When the operation mode is the test mode, a negative logic “0” of the column 35a represents a case that both the data agree with each other, and a positive logic “1” of the column 35a represents a case that both the data disagree with each other.

Further, since the read data mout is not compared and verified with the expected value EXPD in the ordinary operation mode, the values of the column 35a in the ordinary operation mode are the same as those of the read data mout.

As illustrated in FIG. 5A, when the read data of the column 33a is “0”, the verification value of the column 35a is obtained by inverting the verification value when the read data is “1”. For example, in the ordinary operation mode, when the read data is “0”, the verification value is “0” regardless the expected value, and when the read data is “1”, the verification value is “1” regardless the expected value.

Further, in the test mode, when the read data is “0”, the verification value is “1” when the expected value is “0”, and the verification value is “0” when the expected value is “1”. When the read data is “1”, the verification value is “1” when the expected value is “0” and the verification value is “0” when the expected value is “1”. That is, when the operation mode is the ordinary operation mode, the value of the read data agrees with the verification value, and when the operation mode is the test mode, the verification value can be logically calculated using the test signal test, the read data mout, and the expected value EXPD.

FIG. 5B illustrates an example of a table obtained by rearranging the table illustrated in FIG. 5A to determine the verification value by a logic operation. A column numeral 31b represents an operation mode of the memory. A column 32b represents the read data mout. A column 33b represents the test signal test. A column 34b represents the expected value EXPD.

A column 35b represents the verification value or the read data. A column 36b represents AND of the test signal and the expected value EXPD. A column 37b represents the exclusive OR of the AND of the test signal and the expected value and the read data.

As illustrated in FIG. 5B, it can be found that the exclusive OR of the read data and the AND result of the test signal test and the expected value EXPD agree with the verification value or the read data. Accordingly, the memory test circuit 20 outputs the agreement verification value between the expected value and the read data in the test mode and outputs the read data in the ordinary operation mode signal by outputting the exclusive OR of the read data mout and the AND result of the test signal and the expected value. The memory test circuit 20 is used in both the test mode and the ordinary mode. Accordingly, the memory test circuit 20 can test a memory performance using the system clock signal CLK for the ordinary operation.

Embodiments of a memory test circuit using the memory test circuit 20 illustrated in FIG. 2 as a circuit for outputting the exclusive OR of the read data mout and the AND result of the test signal test and the expected value EXPD will be explained below.

### First Embodiment

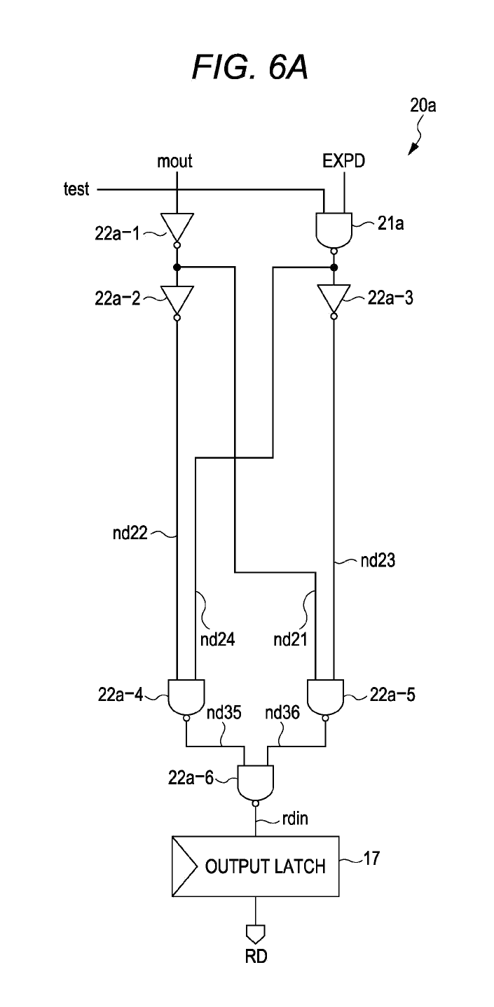

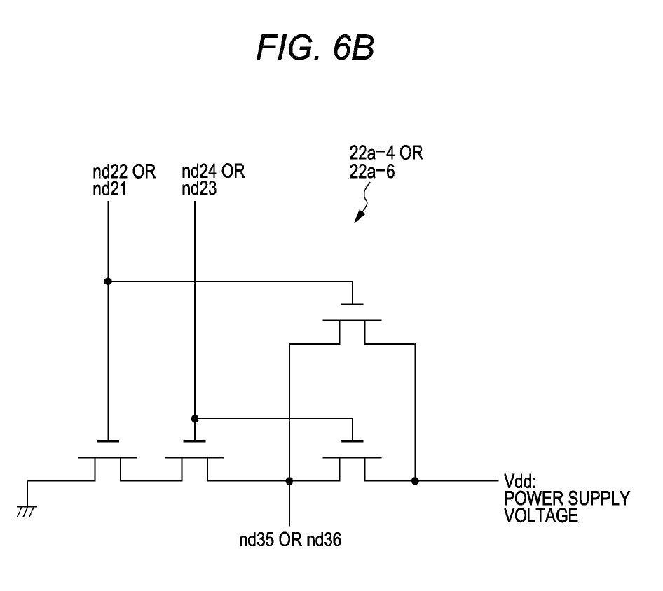

FIG. 6A illustrates a first embodiment of a memory test circuit using a NAND circuit. FIG. 6B illustrates an example of a circuit arrangement of a NAND circuit 22a-4 or 22a-5.

A memory test circuit 20a illustrated in FIG. 6A includes NAND circuits 21a, 22a-4 to 22a-6, and INVERTER circuits 22a-1 to 22a-3. The NAND circuit 21a is an example of the first logic circuit 21 illustrated in FIG. 2. The INVERTER circuits 22a-1 to 22a-3 and the NAND circuits 22a-4 to 22a-6 are an example of the second logic circuit 22 illustrated in FIG. 2.

Reference numeral nd21 illustrated in FIG. 6A denotes an output signal of the INVERTER circuit 22a-1. Reference numeral nd22 illustrated in FIG. 6A denotes an output signal of the INVERTER circuit 22a-2. Reference numeral nd23 illustrated in FIG. 6A denotes an output signal of the INVERTER circuit 22a-3. Reference numeral nd24 illustrated in FIG. 6A denotes an output signal of the NAND circuit 21a. Reference numeral nd35 illustrated in FIG. 6A denotes an output signal of the NAND circuit 22a-4. Reference numeral nd36 illustrated in FIG. 6A denotes an output signal of the NAND circuit 22a-5.

The NAND circuit 21a receives an expected value EXPD and a test signal test and outputs the signal nd24. The signal nd24 is a signal of NAND result of the expected value EXPD and the test signal test.

The INVERTER circuit 22a-3 receives the signal nd24 and outputs the signal nd23. The INVERTER circuit 22a-1 receives read data mout and outputs the signal nd21.

The INVERTER circuit 22a-2 receives the signal nd21 and outputs the signal nd22. The NAND circuit 22a-4 receives the signals nd22 and nd24 and outputs the signal nd35. The NAND circuit 22a-5 receives the signals nd21 and nd23 and outputs the signal nd36. The NAND circuit 22a-6 receives the signals nd35 and nd36 and outputs a signal rdin to an output latch 17.

Note that, as illustrated in FIG. 6B, the NAND circuit 22a-4 or 22a-5 is designed by a circuit having two gate stages. Vdd denotes a power supply voltage.

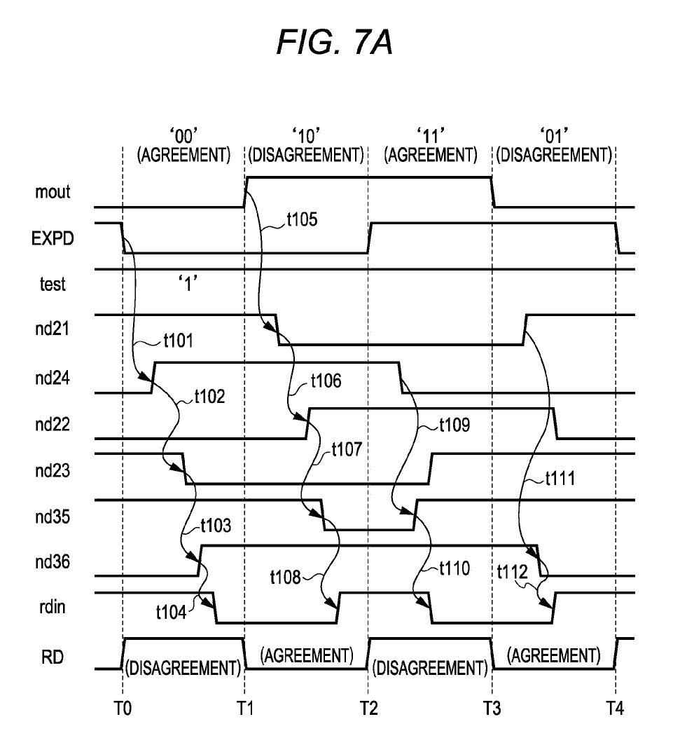

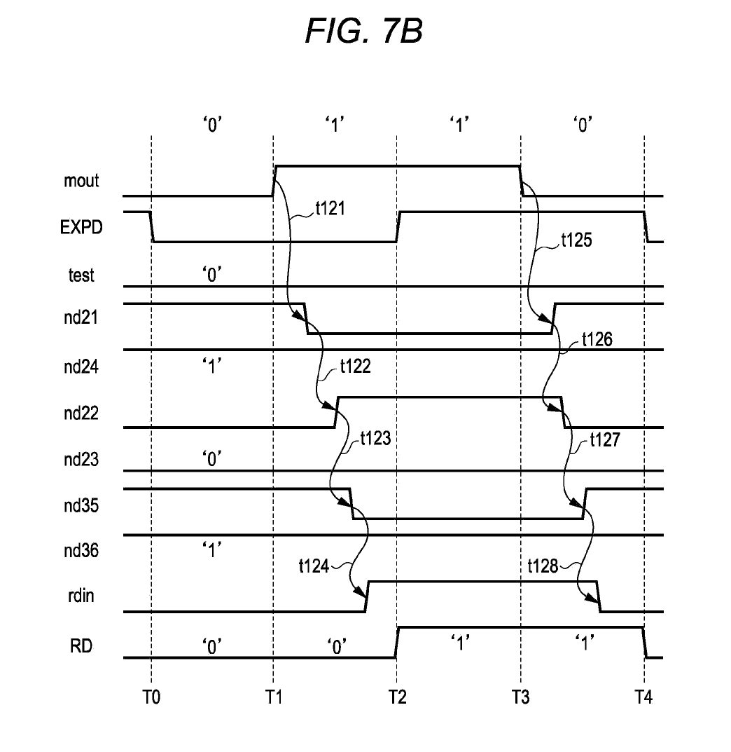

FIG. 7A is a timing chart of signals flowing to the memory test circuit 20a in a test mode. Times [T0, T1, T2, T3] illustrated in FIG. 7A represent beginning of one cycle of a system clock signal CLK, respectively. The signals flowing in the memory test circuit 20a in each time section will be explained below. Further, since the memory test circuit 20a is in the test mode, the test signal test is “1” in the times [T0, T1, T2, T3] illustrated in FIG. 7A. Note that, as illustrated also in FIG. 5B, an output signal “0” of the output latch circuit 17 for outputting an agreement verification value represents that the read data mout agrees with the expected value EXPD, and an output signal “1” thereof represents that the read data mout disagrees with the expected value EXPD.

A timing chart of a time section [T0, T1] illustrated in FIG. 7A will be explained. The time section [T0, T1] illustrated in FIG. 7A represents respective signals when the agreement verification value is output by that the read data mout and the expected value EXPD are set to “0”, respectively.

When the expected value EXPD changes from “1” to “0” in T0, the signal nd24 output from the NAND circuit 21a, to which the expected value EXPD set to “0” and the test signal test set to “1” are input, changes from “0” to “1” in t101. Since the signal nd23 is an output from the NAND circuit 22a-2, to which the signal nd24 set to “1” is input, the signal nd23 changes from “1” to “0” in t102. Since the signal nd21 set to “1” and the signal nd23 set to “0” are input to the NAND circuit 22a-5, the NAND circuit 22a-5 outputs the signal nd36, which changes from “0” to “1”, in t103. Since the signal nd22 set to “0” and the signal nd24 set to “1” are input to the NAND circuit 22a-4, the NAND circuit 22a-4 outputs the signal nd35 set to “1” during the period of [T0, T1]. Then, the NAND circuit 22a-6, to which the signal nd35 set to “1” and the signal nd36 set to “1” are input, outputs the signal rdin, which changes from “1” to “0”, in t104.

The signal rdin is input to the output latch circuit 17, and its value is fixed in the next cycle [T1, T2]. As a result, the signal RD set to a value “0”, which represents that the read data mout agrees with the expected value EXPD, is output from the output latch circuit 17.

A timing chart of a time section [T0, T2] illustrated in FIG. 7A will be explained. The time section [T1, T2] illustrated in FIG. 7A represents signals when the read data mout disagrees with the expected value EXPD by that they are set to “1” and “0”, respectively.

When the read data mout changes from “0” to “1” in T1, the output signal nd21 of the INVERTER circuit 22a-1, to which the read data mout set to “1” is input, changes from “1” to “0” in t105. Further, the output signal nd22 of the INVERTER circuit 22a-2, to which the signal nd21 set to “0” is input, changes from “0” to “1” in t106.

In contrast, the output signal nd24 of the NAND circuit 21a, to which the expected value EXPD set to “0” and the test signal test set to “1” are input, is set to “1” during the period of [T1, T2]. Accordingly, since the signal nd22 set to “1” and the signal nd24 set to “1” are input to the NAND circuit 22a-4, the NAND circuit 22a-4 outputs the signal nd35, which changes from “1” to “0”, in t107. Since the signal nd21 set to “0” and the signal nd23 set to “0” are input to the NAND circuit 22a-5, the NAND circuit 22a-5 outputs the signal nd36, which set to “1”, during the period of [T1, T2]. Then, the NAND circuit 22a-6, to which the signal nd35 set to “0” and the signal nd36 set to “1” are input, outputs the signal rdin which changes from “0” to “1” in t108.

The signal rdin is input to the output latch circuit 17, and its value is fixed in the next cycle [T2, T3]. As a result, the signal RD set to a value “1”, which represents that the read data mout disagrees with the expected value EXPD, is output from the output latch circuit 17.

A timing chart of a time section [T2, T3] illustrated in FIG. 7A will be explained. The time section [T2, T3] illustrated in FIG. 7A represents signals when the read data mout and the expected value EXPD are set to “1”, respectively.

When the expected value EXPD changes from “0” to “1” in T2, since the NAND circuit 21a receives the expected value EXPD set to “1” and the test signal test set to “1”, the NAND circuit 21a outputs the signal nd24 which changes from “1” to “0”. Since the NAND circuit 22a-4 receives the signal nd24 set to “0” and the signal nd22 set to “1”, the NAND circuit 22a-4 outputs the signal nd35, which changes from “0” to “1”, in t109. Since the NAND circuit 22a-6 receives the signal nd35 set to “1” and the signal nd36 set to “1”, the NAND circuit 22a-6 outputs the signal rdin, which changes from “1” to “0”, in t110.

Since the signal rdin is input to the output latch circuit 17 and its value is fixed in the next cycle [T3,T4], the signal RD set to the value “0” to represent that the read data mout agrees with the expected value EXPD is output from the output latch circuit 17.

A timing chart of a time section [T3, T4] illustrated in FIG. 7A will be explained. The time section [T3, T4] illustrated in FIG. 7A represents signals when the read data mout disagrees with the expected value EXPD by that they are set to “0” and “1”, respectively.

When the read data mout changes from “1” to “0” in T3, the output signal nd21 output from the INVERTER circuit 22a-1, to which the read data mout set to “0” is input, changes from “0” to “1”. Further, since the signal nd21 set to “1” is input to the INVERTER circuit 22a-2, the INVERTER circuit 22a-2 outputs the signal nd22 which changes from “1” to “0”. Since the signal nd21 set to “1” and the signal nd23 set to “1” are input to the NAND circuit 22a-5, the NAND circuit 22a-5 outputs the signal nd36, which changes from “1” to “0”, in t111. Then, as illustrated in t112, the NAND circuit 22a-6, to which the signal nd35 set to “1” and the signal nd36 set to “0” are input, outputs the signal rdin set to “1”.

Since the signal rdin is input to the output latch circuit 17 and its value is fixed in the next cycle [T4,T5], the signal RD set to a value “1” to represent that the read data mout disagrees with the expected value EXPD is output from the output latch circuit 17. The signal “1” of the output latch circuit 17 represents disagreement.

As described above, the memory test circuit 20a, which outputs the exclusive OR of the read data mout and the AND of the test signal test and the expected value EXPD, can output the agreement verification value of the expected value EXPD and the read data in a test.

FIG. 7B is a timing chart of signals flowing to the memory test circuit 20a in an ordinary operation mode. Times [T0, T1, T2, T3] illustrated in FIG. 7B represent beginning of one cycle of a clock signal, respectively. The signals flowing to the memory test circuit 20a in each time section will be explained below. In the time section [T0, T1, T2, T3], since the memory test circuit 20a is in the ordinary operation mode, the test signal test illustrated in FIG. 7B is set to “0”.

States of the respective signals in the time section [T0, T1] illustrated in FIG. 7B will be explained. During the period of [T0, T1], the signal nd21 output from the INVERTER circuit 22a-1, to which a read signal mout set to “0” is input, is set to “1” during the period of [T0, T1]. Although the expected value EXPD changes from “1” to “0” in T0, the value of the signal nd24 output from the NAND circuit 21a, to which the expected value EXPD set to “0” and the test signal test set to “0” are input, is “1” during the period of [T0, T1]. Since the signal nd21 does not change from “1” during the period of [T0, T1], the signal nd22 output from the INVERTER circuit 22a-2, to which the signal nd21 is input, is “0” during the period of [T0, T1]. Since the signal nd24 does not change from “1” during the period of [T0, T1], the signal nd23 output from the INVERTER circuit 22a-2, to which the signal nd24 is input, is “0” during the period of [T0, T1].

As described above, since the signals nd21 to nd24 do not change during the period of [T0, T1], the signals output from the NAND circuits 22a-4, 22a-5, 22a-6 of a rear stage do not change during the period of [T0, T1]. Accordingly, during the period of [T0, T1], the value of the signal nd35 is “1”, the value of the signal nd36 is “1”, the value of the signal rdin is “0”, and the value of the signal RD is “0”.

A timing chart of a time section [T1, T2] illustrated in FIG. 7B will be explained. In the time section [T1, T2], the read signal mout is “1”.

When the read signal mout changes from “0” to “1” in T1, the signal nd21 output from the INVERTER circuit 22a-1, to which the read signal mout is input, changes from “1” to “0”. Further, the signal nd22 output from the INVERTER circuit 22a-2, to which the signal nd21 is input, changes from “0” to “1” in t122. Further, the signal nd24 output from the NAND circuit 21a, to which the test signal test set to “0” and the expected value EXPD set to “0” are input, is set to “1” during the period of [T1, T2]. The signal nd23 output from the INVERTER circuit 22a-3, to which the signal nd24 set to “1” is input, is set to “0” during the period of [T1, T2].

The NAND circuit 22a-4 receives the signal nd22 set to “1” and the signal nd24 set to “1” and outputs the signal nd35, which changes from “1” to “0”, in t123. The NAND circuit 22a-5 receives the signal nd21 set to “0” and the signal nd23 set to “0” and outputs the signal nd36 set to “1” during the period of [T1, T2]. The NAND circuit 22a-6 receives the signal nd35 set to “0” and the signal nd36 set to “1” and outputs the signal rdin, which changes from 0” to “1”, in t124.

The signal rdin is input to the output latch circuit 17 and its value is fixed in the next cycle [T2, T3]. As a result, the signal RD whose value is set to “1” is output from the output latch circuit 17.

A timing chart of a time section [T2, T3] illustrated in FIG. 7B will be explained. During the period of [T2, T3], the signal nd21 output from the INVERTER circuit 22a-1, to which the read signal mout set to “1” is input, is set to “0” during the period of [T2,T3]. Although the expected value EXPD changes from “0” to “1” in T2, the value of the signal nd24 output from the NAND circuit 21a, to which the expected value EXPD set to “1” and the test signal test set to “0” are input, is “1” during the period of [T2, T3]. Since the signal nd21 does not change from “0” during the period of [T2, T3], the signal nd22 output from the INVERTER circuit 22a-2, to which the signal nd21 is input, is “1” during the period of [T2, T3]. Since the signal nd24 does not change from “1” during the period of [T2, T3], the signal nd23 output from the INVERTER circuit 22a-2, to which the signal nd24 is input, is “0” during the period of [T2, T3].

As described above, since the signals nd21 to nd24 do not change during the period of [T2, T3], the signals output from the NAND circuits 22a-4, 22a-5, 22a-6 of a rear stage do not change during the period of [T2, T3]. Accordingly, during the period of [T2, T3], the value of the signal nd35 is “0”, the value of the signal nd36 is “1”, the value of the signal rdin is “1”, and the value of the signal RD is “1”.

A timing chart of a time section [T3, T4] illustrated in FIG. 7B will be explained. In the time section [T3, T4], the read signal mout is “0”.

When the read signal mout changes from “1” to “0” in T3, the output signal nd21 output from the INVERTER circuit 22a-1, to which the read signal mout is input, is set to “1” in t125. The signal nd22 output from the INVERTER circuit 22a-2, to which the signal nd21 is input, changes from “1” to “0” in t126. Further, the signal nd24 output from the NAND circuit 21a, to which the test signal test set to“0” and the expected value EXPD set to “1” are input, is “1” during the period of [T3, T4]. The signal nd35 output from the NAND circuit 22b-4, to which the signal nd22 set to “0” and the signal nd24 set to “1” are input, changes from “0” to “1” in t127. The NAND circuit 22a-5 receives the signal nd21 set to “1” and the signal nd23 set to “0” and outputs the signal nd36 set to “1”. The NAND circuit 22a-6 receives the signal nd35 set to “1” and the signal nd36 set to “1” and outputs the signal rdin, which changes from “1” to “0”, in t128. The signal rdin is input to the output latch circuit 17 and fixed in the next cycle [T4, T5], and the signal RD set to “0” is output from the output latch circuit 17.

As described above, when the test signal test has a logic value of “0”, the memory test circuit 20a can output the value of the read signal mout as it is.

### Second Embodiment

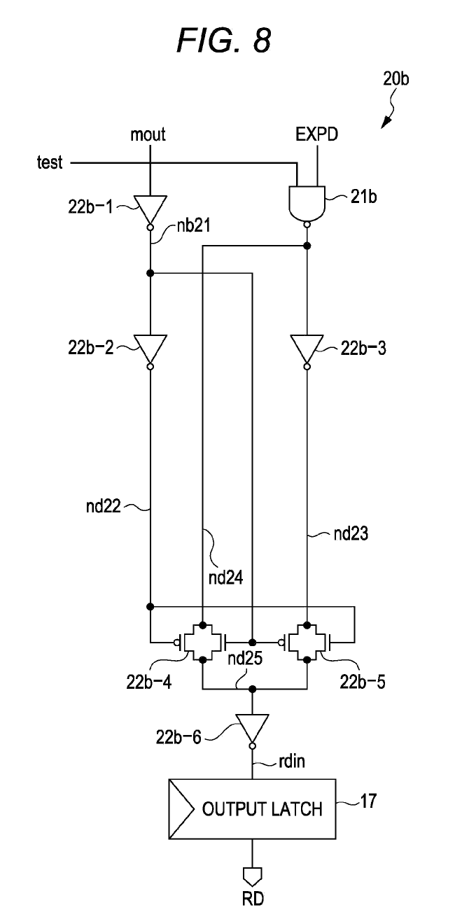

FIG. 8 illustrates a second embodiment of the memory test circuit using transfer gate circuits. Reference numeral 20b illustrated in FIG. 8 denotes a memory test circuit according to the second embodiment, 21b denotes a NAND circuit, 22b-1, 22b-2, 22b-3, and 22b-6 denote NAND circuits, and 22b-4 and 22b-5 denote the transfer gate circuits. Reference numeral 17 denotes an output latch circuit.

The memory test circuit 20b includes the NAND circuit 21b, the INVERTER circuits 22b-1, 22b-2, 22b-3, 22b-6, and the transfer gate circuits 22b-4, 22b-5. The NAND circuit 21b, to which a test signal test and an expected value EXPD are input, is an example of the first logic circuit 21 illustrated in FIG. 2. The INVERTER circuits 22b-1, 22b-2, 22b-3, 22b-6 and the transfer gate circuits 22b-4, 22b-5 are an example of the second logic circuit 22 illustrated in FIG. 2.

Reference numeral nd21 illustrated in FIG. 8 denotes an output signal of the INVERTER circuit 22b-1. Reference numeral nd22 illustrated in FIG. 8 denotes an output signal of the INVERTER circuit 22b-2. Reference numeral nd24 illustrated in FIG. 8 denotes an output signal of the NAND circuit 21b. Reference numeral nd23 illustrated in FIG. 8 denotes an output of the INVERTER circuit 22b-3. Reference numeral nd25 illustrated in FIG. 8 denotes an output signal of the transfer gate circuits 22b-4, 22b-5.

Since the NAND circuit 21b and the INVERTER circuits 22b-1 to 22b-3 illustrated in FIG. 8 have the same circuit arrangements as those of the NAND circuit 21a and the INVERTER circuits 22a-1 to 22a-3 illustrated in FIG. 6A, respectively, the explanation thereof is omitted.

Each of the transfer gate circuits is composed of an n-channel transistor disposed in parallel with a p-channel transistor. Each transfer gate circuit is placed in a conductive state or in a non-conductive state by inputting signals to gate terminals of respective transistors so that the signals are inverted from each other.

The signal nd24 is input to the source terminal of the transfer gate circuit 22b-4. The signal nd22 is input to a gate terminal of the p-channel transistor of the transfer gate circuit 22b-4, and the signal nd21 is input to a gate terminal of the n-channel transistor.

The signal nd23 is input to a source terminal of the transfer gate circuit 22b-5. The signal nd21 is input to a gate terminal of the p-channel transistor of the transfer gate circuit 22b-5, and the signal nd22 is input to a gate terminal of the n-channel transistor. The INVERTER circuit 22b-6 receives the signal nd25 and outputs a signal rdin.

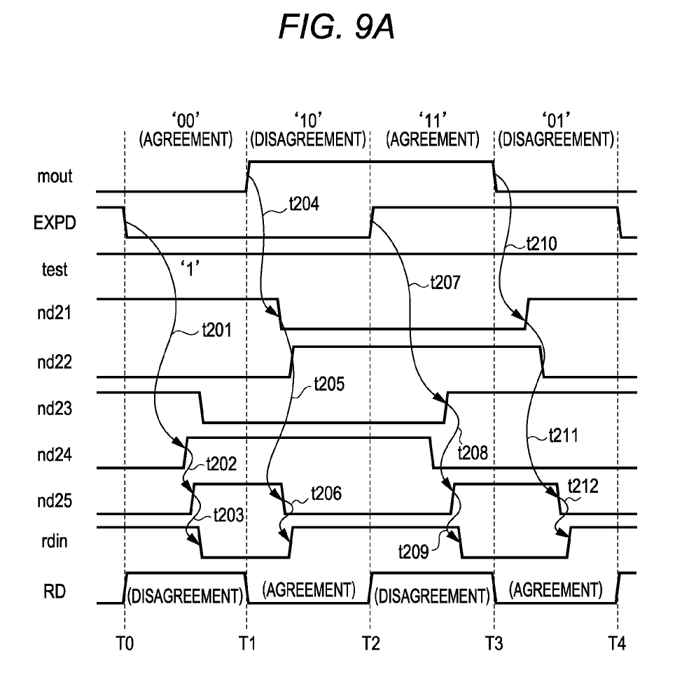

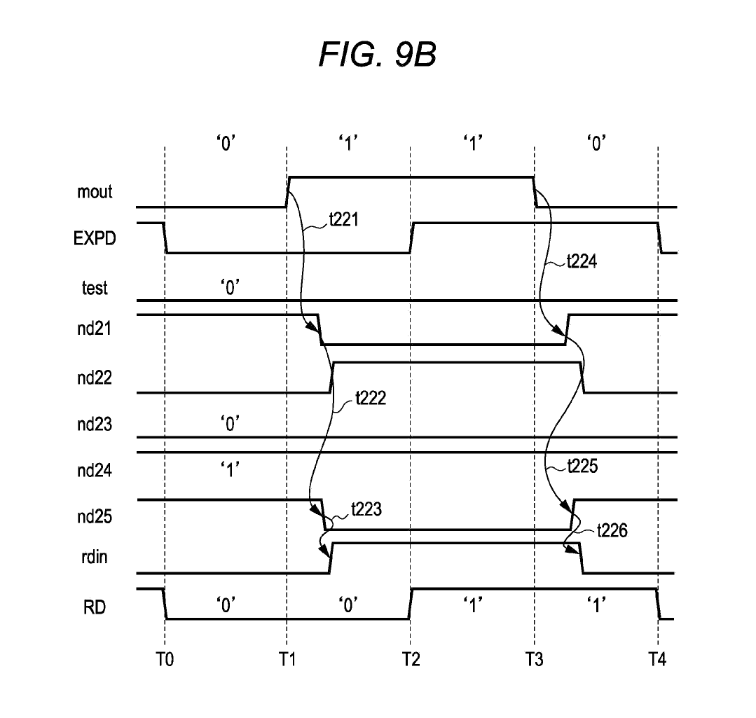

FIG. 9A is a timing chart of signals flowing to the memory test circuit 20b in a test mode. A time section [T0, T1, T2, T3] illustrated in FIG. 9A represent beginning of one cycle of a clock signal, respectively. A timing chart of the signals flowing to the memory test circuit 20b in each time section will be explained below. Since the memory test circuit 20b is in the test mode, the test signal test illustrated in FIG. 9A is “1” in the time section [T0, T1, T2, T3]. Note that, as illustrated also in FIG. 5B, an output signal “0” of the output latch circuit 17 for outputting an agreement verification value represents that the read data mout agrees with the expected value EXPD, and an output signal “1” thereof represents that the read data mout disagrees with the expected value EXPD.

A timing chart of a time section [T0, T1] illustrated in FIG. 9A will be explained. The time section [T0, T1] illustrated in FIG. 9A represents a timing chart in which the read mout agrees with the expected value EXPD by that they are set to “0”, respectively.

When the expected value EXPD changes from “1” to “0” in T0, the signal nd24 output from the NAND circuit 21b, to which the expected value EXPD set to “0” and the test signal test set to “1” are input, changes from “0” to “1” in t201. In the transfer gate circuit 22b-4, since the signal nd22 input to the gate of the p-channel transistor is “0” as well as the signal nd21 input to the gate of the n-channel transistor is “1”, the transfer gate circuit 22b-4 is placed in the conductive state. In contrast, in the transfer gate circuit 22b-5, since the signal nd21 input to the gate of the p-channel transistor is “1” as well as the signal nd22 input to the gate of the n-channel transistor is “0”, the transfer gate circuit 22b-5 is placed in the non-conductive state.

In the transfer gate circuit 22b-4 in the conductive state, when the signal nd24 input to the source terminal changes from “0” to “1” in the t201, the signal nd25 output from a drain terminal changes from “0” to “1” in t202. Further, the INVERTER circuit 22b-6, to which the signal nd25 is input, outputs the signal rdin which is obtained by inverting the value “1” of the signal nd25 to “0” in t203. The signal rdin is input to the output latch circuit 17 and fixed in the next cycle [T1, T2], and a signal RD set to “0” is output from the output latch circuit 17.

A timing chart of a time section [T1, T2] illustrated in FIG. 9A will be explained. The time section [T1, T2] illustrated in FIG. 9A represents a timing chart in which the read mout disagrees with the expected value EXPD by that they are set to “1” and “0”, respectively.

When the read mout changes from “0” to “1” in T1, the signal nd21 output from the INVERTER circuit 22b-1, to which the read data mout set to “1” is input, changes from “1” to “0” in t204. Further, the signal nd22 output from the INVERTER circuit 22b-2, to which the signal nd21 is input, changes from “1” to “0”. In the transfer gate circuit 22b-5, since the signal nd21 input to the gate of the p-channel transistor is “0” as well as the signal nd22 input to the gate of the n-channel transistor is “1”, the transfer gate circuit 22b-5 is placed in the conductive state. In contrast, in the transfer gate circuit 22b-4, since the signal nd22 input to the gate of the p-channel transistor is “1” as well as the signal nd21 input to the gate of the n-channel transistor is “0”, the transfer gate circuit 22b-4 is placed in the non-conductive state.

In the transfer gate circuit 22b-5 in the conductive state, since the signal nd23 input to the source terminal is set to “0”, the signal nd25 output from a drain terminal changes from “1” to “0” in t205. Further, the INVERTER circuit 22b-6, to which the signal nd25 set to “0” is input, outputs the signal rdin, which changes from “0” to “1”, in t206.

The signal rdin is input to the output latch circuit 17 and fixed in the next cycle [T3, T4], and the signal RD set to a value “1” to represent that the read mout disagrees with the expected value EXPD is output from the output latch circuit 17.

A timing chart of a time section [T2, T3] illustrated in FIG. 9A will be explained. The time section [T2, T3] illustrated in FIG. 9A represents a timing chart in which the read data mout agrees with the expected value EXPD by that they are set to “1”, respectively.

When the expected value EXPD changes from “0” to “1” in T2, the signal nd24 output from the NAND circuit 21b, to which the expected value EXPD is input, changes from “1” to “0” in t207. In the transfer gate circuit 22b-4, since the signal nd22 input to the gate of the p-channel transistor is “1” as well as the signal nd21 input to the gate of the n-channel transistor is “0”, the transfer gate circuit 22b-4 is placed in the non-conductive state. In contrast, since the signal nd21 input to the gate of the p-channel transistor is “0” and the signal nd22 input to the gate of the n-channel transistor is “1”, the transfer gate circuit 22b-5 is placed in the conductive state.

When the signal nd23, which is input to the source terminal of the transfer gate circuit 22b-5 in the conductive state is set to “1”, the signal nd25 output from the drain terminal changes from “0” to “1” in t208. Further, the INVERTER circuit 22b-6, to which the signal nd25 is input, outputs the signal rdin, which changes from “1” to “0”, in t206.

The signal rdin is input to the output latch circuit 17 and fixed in the next cycle [T3, T4], and the signal RD set to a value “0” to represent that the read data mout agrees with the expected value EXPD is output from the output latch circuit 17.

A timing chart of a time section [T3, T4] illustrated in FIG. 9A will be explained. A time section [T3, T4] illustrated in FIG. 9A represents a timing chart in which the read data mout disagrees with the expected value EXPD by that they are set to “0” and “1”, respectively.

When the read data mout changes from “1” to “0” in T3, the signal nd21 output from the INVERTER circuit 22b-1, to which the read data mout set to “0” is input, changes from “0” to “1” in t210. Further, the signal nd22 output from the INVERTER circuit 22b-1, to which the signal nd21 set to “1” is input, changes from “1” to “0”. Since the signal nd22 input to the gate of the p-channel transistor is “0” as well as the signal nd21 input to the gate of the n-channel transistor is “1”, the transfer gate circuit 22b-4 is placed in the conductive state. In contrast, since the signal nd21 input to the gate of the p-channel transistor is “1” and the signal nd22 input to the gate of the n-channel transistor is “0”, the transfer gate circuit 22b-5 is placed in the non-conductive state.

Since the signal nd24 input to the source terminal of the transfer gate circuit 22b-4 in the conductive state is set to “0”, the signal nd25 output from the drain terminal changes from “1” to “0” in t211. Further, the INVERTER circuit 22b-6, to which the signal nd25 is input, outputs the signal rdin which is obtained by inverting the value “0” of the signal nd25 to “1” in t212.

The signal rdin is input to the output latch circuit 17 and fixed in the next cycle [T3, T4], and the signal RD set to a value “1” to represent that the read data mout disagrees with the expected value EXPD is output from the output latch circuit 17.

As described above, the memory test circuit 20b, which outputs the exclusive OR of the read data mout and the AND result of the test signal test and the expected value EXPD, can output the agreement verification value of the expected value EXPD and the read data in a test.

FIG. 9B is a timing chart of signals flowing in the memory test circuit 20b in an ordinary operation mode. Times [T0, T1, T2, T3] illustrated in FIG. 9B represent beginning of one cycle of a clock signal, respectively. The signals flowing in the memory test circuit 20b in each time section will be explained below. In the time section [T0, T1, T2, T3], since the memory test circuit 20b is in the ordinary operation mode, the test signal test illustrated in FIG. 9B is set to “0”.

States of the respective signals in a time section [T0, T1] illustrated in FIG. 9B will be explained. During the period of [T0, T1], the signal nd21 output from the INVERTER circuit 22b-1, to which the read signal mout set to “0” is input, is set to “1” during the period of [T0, T1].

Although the expected value EXPD changes from “1” to “0” in T0, the value of the signal nd24 output from the NAND circuit 21b, to which the expected value EXPD whose value is set to “0” and the test signal test whose value is set to “0” are input, is “1” during the period of [T0, T1].

Since the signal nd21 does not change from “1” during the period of [T0, T1], the signal nd22 output from the INVERTER circuit 22b-2, to which the signal nd21 is input, is “0” during the period of [T0, T1]. Since the signal nd24 does not change from “1” during the period of [T0, T1], the signal nd23 output from the INVERTER circuit 22b-2, to which the signal nd24 is input, is “0” during the period of [T0, T1].

As described above, since the signals nd21 to nd24 do not change during the period of [T0, T1], the signals output from the transfer gate circuits 22b-4 to 22a-6 of a rear stage do not change during the period of [T0, T1]. Accordingly, during the period of [T0, T1], the value of the signal nd25 is “1”, the value of the signal rdin is “0”, and the value of the signal RD is “0”.

A timing chart of a time section [T1, T2] illustrated in FIG. 9B will be explained. In the time section [T1, T2], the read signal mout is “1”.

When the read signal mout changes from “0” to “1” in T1, the signal nd21 output from the INVERTER circuit 22b-1, to which the read signal mout is input, changes from “1” to “0” in t221. Further, the signal nd22 output from the INVERTER circuit 22b-2, to which the signal nd21 is input, changes from “0” to “1”. Further, the signal nd24 output from the NAND circuit 21b, to which the test signal test set to“0” and the expected value EXPD set to “0” are input, is “1” during the period of [T1, T2]. The signal nd23 output from the INVERTER circuit 22b-3, to which the signal nd24 set to “1” is input, is “0” during the period of [T1, T2].

In the transfer gate circuit 22b-4, since the signal nd22 input to the gate of the p-channel transistor is “1” as well as the signal nd21 input to the gate of the n-channel transistor is “0”, the transfer gate circuit 22b-4 is placed in the non-conductive state. In contrast, in the transfer gate circuit 22b-5, since the signal nd21 input to the gate of the p-channel transistor is “0” and the signal nd22 input to the gate of the n-channel transistor is “1”, the transfer gate circuit 22b-5 is placed in the conductive state.

When the signal nd23 input to the source terminal of the transfer gate circuit 22b-5 in the conductive state is set to “0”, the signal nd25 output from the drain terminal changes from “1” to “0” in t222. Further, the INVERTER circuit 22b-6, to which the signal nd25 set to “0” is input, outputs the signal rdin, which changes from “0” to “1”, in t223. The signal rdin is input to the output latch circuit 17 and fixed in the next cycle [T2, T3], and the signal RD set to “1” is output from the output latch circuit 17.

A timing chart of a time section [T2, T3] illustrated in FIG. 9B will be explained. During the period of [T2, T3], the signal nd21 output from the INVERTER circuit 22b-1, to which the read signal mout set to “1” is input, is “0” during the period of [T2, T3]. Although the expected value EXPD changes from “0” to “1” in T2, the value of the signal nd24 output from the NAND circuit 21b, to which the expected value EXPD set to “1” and the test signal test set to “0” are input, is “1” during the period of [T2, T3]. Since the signal nd21 does not change from “0” during the period of [T2, T3], the signal nd22 output from the INVERTER circuit 22b-2, to which the signal nd21 is input, is “1” during the period of [T2, T3]. Since the signal nd24 does not change from “1” during the period of [T2, T3], the signal nd23 output from the INVERTER circuit 22b-2, to which the signal nd24 is input, is “0” during the period of [T2, T3].

As described above, since the signals nd21 to nd24 do not change during the period of [T2, T3], the signals output from the transfer gate circuits 22b-4 to 22a-6 of a rear stage do not change during the period of [T0, T1]. Accordingly, during the period of [T2, T3], the value of the signal nd25 is “0”, the value of the signal rdin is “1”, and the value of the signal RD is “1”.

A timing chart of a time section [T3, T4] illustrated in FIG. 9B will be explained. When the read signal mout changes from “1” to “0” in T3, the signal nd21 output from the INVERTER circuit 22b-1, to which the read signal mout is input, changes from “0” to “1” in t224. Further, the signal nd22 output from the INVERTER circuit 22b-2, to which the signal nd21 is input, changes from “1” to “0”. Further, the signal nd24 output from the NAND circuit 21b, to which the test signal test set to “0” and the expected value EXPD set to “1” are input, is “1” during the period of [T3, T4]. The signal nd23 output from the INVERTER circuit 22b-3, to which the signal nd24 set to “1” is input, is set to “0”.

In the transfer gate circuit 22b-4, since the signal nd22 input to the gate of the p-channel transistor is “0” as well as the signal nd21 input to the gate of the n-channel transistor is “1”, the transfer gate circuit 22b-4 is placed in the conductive state. In contrast, in the transfer gate circuit 22b-5, since the signal nd21 input to the gate of the p-channel transistor is “1” and the signal nd22 input to the gate of the n-channel transistor is “0”, the transfer gate circuit 22b-5 is placed in the non-conductive state.

When the signal nd24, which is input to the source terminal of the transfer gate circuit 22b-4 in the conductive state is set to “1”, the signal nd25 output from the drain terminal changes from “0” to “1” in t225. Further, the INVERTER circuit 22b-6, to which the signal nd25 is input, outputs the signal rdin, which is obtained by inverting the value “1” of the nd25 to “0” in t226. The signal rdin is input to the output latch circuit 17 and fixed in the next cycle [T4, T5], and the signal RD whose value is “0” is output from the output latch circuit 17.

As described above, when the test signal test is a logic value “0”, the memory test circuit 20a can output the value of the read signal mout as it is.

### Third Embodiment

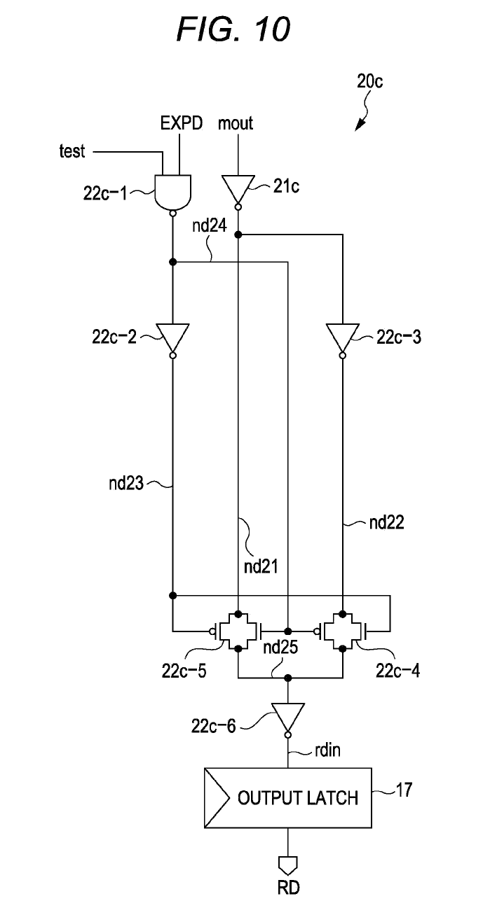

FIG. 10 illustrates a third embodiment of the memory test circuit using transfer gate circuits. Reference numeral 20C illustrated in FIG. 10 denotes a memory test circuit according to the third embodiment, 21c, 22c-2, 22c-3, 22c-5, and 22C-6 denote INVERTER circuits, 22c-1 denotes a NAND circuit, and 22c-4 and 22c-5 denote the transfer gate circuits. Reference numeral 17 denotes an output latch circuit.

The memory test circuit 20c includes the NAND circuit 22c-1, the INVERTER circuits 21c, 22c-2, 22c-3, and 22c-6, and the transfer gate circuits 22c-4 and 22c-5. The NAND circuit 21c, to which a test signal test and an expected value EXPD are input, is an example of the first logic circuit 21 illustrated in FIG. 2. The INVERTER circuits 21c, 22c-2, 22c-3, and 22c-6 and the transfer gate circuits 22c-4 and 22c-5 are an example of the second logic circuit 22 illustrated in FIG. 2.

Reference numeral nd21 illustrated in FIG. 10 denotes an output signal of the INVERTER circuit 21c. Reference numeral nd22 illustrated in FIG. 10 denotes an output signal of the INVERTER circuit 22c-3. Reference numeral nd24 illustrated in FIG. 10 denotes an output signal of the NAND circuit 21c-1. Reference numeral nd23 illustrated in FIG. 8 denotes an output signal of the INVERTER circuit 22c-2. Reference numeral nd25 illustrated in FIG. 10 denotes an output signal of the transfer gate circuits 22c-4 and 22c-5.

Since the INVERTER circuit 21c, the NAND circuit 22c-1, and the INVERTER circuits 22c-2 to 22c-3 illustrated in FIG. 10 have the same circuit arrangements as those of the NAND circuit 21a and the INVERTER circuits 22a-1 to 22a-3 illustrated in FIG. 6A, respectively, the explanation thereof is omitted.

The signal nd22 is input to a source terminal of the transfer gate circuit 22c-4. The signal nd23 is input to a gate terminal of an n-channel transistor of the transfer gate circuit 22c-4, and the signal nd24 is input to a gate terminal of a P-channel transistor.

The signal nd21 is input to a source terminal of the transfer gate circuit 22c-5. The signal nd24 is input to a gate terminal of the n-channel transistor of the transfer gate circuit 22c-5, and the signal nd23 is input to a gate terminal of the P-channel transistor. The INVERTER circuit 22c-6 receives the signal nd25 and outputs a signal rdin.

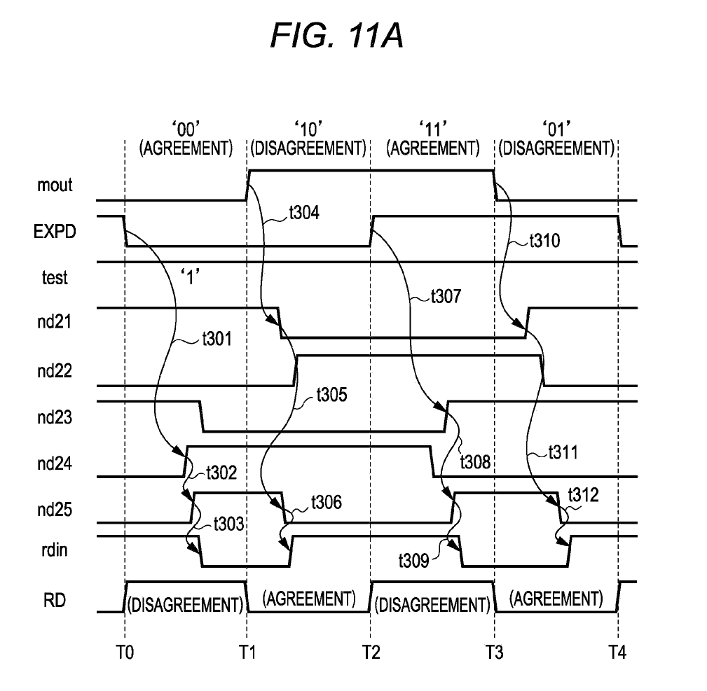

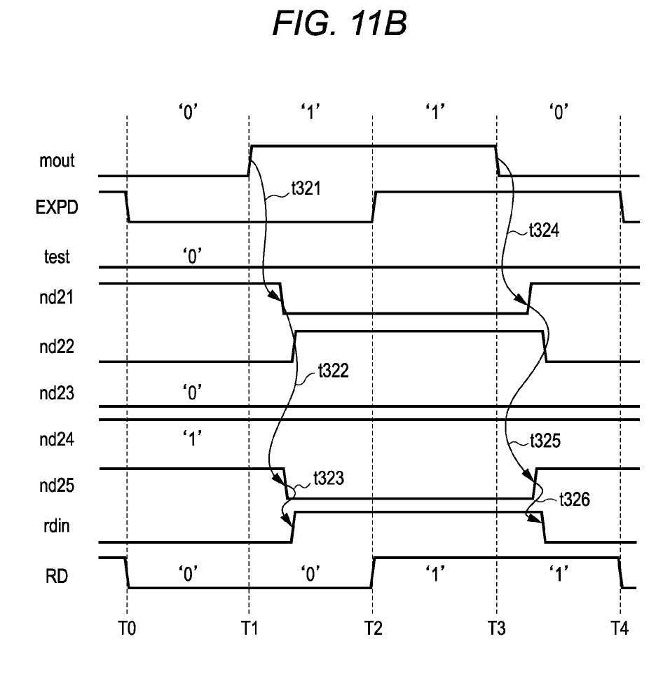

FIG. 11A is a timing chart of signals flowing to the memory test circuit 20c in a test mode. A time section [T0, T1, T2, T3] illustrated in FIG. 11A represent beginning of one cycle of a clock signal, respectively. The timing char of the signals flowing to the memory test circuit 20c in each time section will be explained below. Since the memory test circuit 20c is in the test mode, the test signal test illustrated in FIG. 11A is “1” in a time section [T0, T1, T2, T3]. Note that, as illustrated also in FIG. 5B, an output signal “0” of the output latch circuit 17 for outputting an agreement verification value represents that the read data mout agrees with the expected value EXPD, and an output signal “1” thereof represents that the read data mout disagrees with the expected value EXPD.

A timing chart of a time section [T0, T1] illustrated in FIG. 11A will be explained. The time section [T0, T1] illustrated in FIG. 11A represents a timing chart in which the read mout agrees with the expected value EXPD by that they are set to “0”, respectively.

When the expected value EXPD changes from “1” to “0” in T0, the signal nd24 output from the NAND circuit 22c-1, to which the expected value EXPD set to “1” and the test signal test set to “1” are input, changes from “0” to “1” in t301. In the transfer gate circuit 22c-4, since the signal nd24 input to the gate of the p-channel transistor is “1” as well as the signal nd23 input to the gate of the n-channel transistor is “0”, the transfer gate circuit 22c-4 is placed in a non-conductive state. In contrast, in the transfer gate circuit 22c-5, since the signal nd22 input to the gate of the p-channel transistor is “0” as well as the signal nd24 input to the gate of the n-channel transistor is “1”, the transfer gate circuit 22c-5 is placed in a conductive state.

When the signal nd21, which is input to the source terminal of the transfer gate circuit 22c-5 in the conductive state is set to “1”, the signal nd25 output from a drain terminal changes from “0” to “1” in t302. Further, the INVERTER circuit 22c-6, to which the signal nd25 is input, outputs the signal rdin which is obtained by inverting the value “1” of the signal nd25 to “0” in t303. The signal rdin is input to the output latch circuit 17 and fixed in the next cycle [T1, T2], and a signal RD whose value is “0” is output from the output latch circuit 17.

A timing chart of a time section [T1, T2] illustrated in FIG. 11A will be explained. The time section [T1, T2] illustrated in FIG. 11A represent a timing chart in which the read data mout disagrees with the expected value EXPD by that they are set to “1” and “0”, respectively.

When the read data mout changes from “0” to “1” in T1, the signal nd21 output from the INVERTER circuit 21c, to which the read data mout set to “1” is input, changes from “1” to “0” in t304. Further, the signal nd22 output from the INVERTER circuit 22c-3, to which the signal nd21 is input, changes from “0” to “1”. In the transfer gate circuit 22c-5, since the signal nd23 input to the gate of the p-channel transistor is “0” as well as the signal nd24 input to the gate of the n-channel transistor is set to “1”, the transfer gate circuit 22c-5 is placed in the conductive state. In contrast, in the transfer gate circuit 22c-4, since the signal nd24 input to the gate of the p-channel transistor is “1” as well as the signal nd23 input to the gate of the n-channel transistor is “0”, the transfer gate circuit 22c-4 is placed in the non-conductive state.

Since the signal nd21 input to the source terminal of the transfer gate circuit 22c-5 in the conductive state is “0”, the signal nd25 output from the drain terminal is changed from “1” to “0” in t305. Further, the INVERTER circuit 22b-6, to which the signal nd25 set to “0” is input, outputs the signal rdin, which changes from “0” to “1”, in t306.

The signal rdin is input to the output latch circuit 17 and fixed in the next cycle, and the signal RD set to a value “1” to represent that the read data mout disagrees with the expected value EXPD is output from the output latch circuit 17.

A timing chart of a time section [T2, T3] illustrated in FIG. 11A will be explained. The timing section [T2, T3] illustrated in FIG. 11A represents a timing chart in which the read data mout agrees with the expected value EXPD by that they are set to “1” and “1”, respectively.

When the expected value EXPD changes from “0” to “1” in T2, the signal nd24 output from the NAND circuit 22c-1, to which the expected value EXPD is input, changes from “1” to “0” at t307. In the transfer gate circuit 22c-4, since the signal nd24 input to the gate of the p-channel transistor is “0” as well as the signal nd23 input to the gate of the n-channel transistor is “1”, the transfer gate circuit 22c-4 is placed in the conductive state. In contrast, in the transfer gate circuit 22c-5, since the signal nd23 input to the gate of the p-channel transistor is “1” as well as the signal nd24 input to the gate of the n-channel transistor is “0”, the transfer gate circuit 22c-5 is placed in the non-conductive state.

When the signal nd22 input to the source terminal of the transfer gate circuit 22c-4 in the conductive state changes from “0” to “1” in the t308, the signal nd25 output from a drain terminal changes from “0” to “1”. Further, the INVERTER circuit 22c-6, to which the signal nd25 is input, outputs the signal rdin, which changes from “1” to “0”, in t309.

The signal rdin is input to the output latch circuit 17 and fixed in the next cycle [T3,T4], and the signal RD set to “0” to represent that the read data mout agrees with the expected value EXPD is output from the output latch circuit 17.

A timing chart of a time section [T3, T4] illustrated in FIG. 11A will be explained. The timing section [T3, T4] illustrated in FIG. 11A represents a timing chart in which the read data mout disagrees with the expected value EXPD by that they are set to “0” and “1”, respectively.

When the read data mout changes from “1” to “0” in T3, the signal nd21 output from the INVERTER circuit 21c, to which the read data mout set to “0” is input, changes from “0” to “1” in t310. Further, the signal nd22 output from the INVERTER circuit 22c-3, to which the signal nd21 set to “1” is input, changes from “1” to “0” in t311. Since the signal nd24 input to the gate of the p-channel transistor is “0” as well as the signal nd23 input to the gate of the n-channel transistor is “1”, the transfer gate circuit 22c-4 is placed in the conductive state. In contrast, since the signal nd23 input to the gate of the p-channel transistor is “1” as well as the signal nd24 input to the gate of the n-channel transistor is “0”, the transfer gate circuit 22c-5 is placed in the non-conductive state.

Since the signal nd24 input to the source terminal of the transfer gate circuit 22c-4 in the conductive state is “0”, the signal nd25 output from the drain terminal is changed from “1” to “0” in t311. Further, the INVERTER circuit 22c-6, to which the signal nd25 is input, outputs the signal rdin which is obtained by inverting the value “0” of the signal nd25 to “1” at t312.

The signal rdin is input to the output latch circuit 17 and fixed in the next cycle, and the signal RD set to a value “1” to represent that the read data mout disagrees with the expected value EXPD is output from the output latch circuit 17.

As described above, the memory test circuit 20c, which outputs the exclusive OR of the read data mout and the AND result of the test signal test and the expected value EXPD, can output the agreement verification value of the expected value EXPD and the read data in a test.

FIG. 11B is a timing chart of signals flowing in the memory test circuit 20c in an ordinary operation mode. Times [T0, T1, T2, T3] illustrated in FIG. 11B represent beginning of one cycle of a clock signal, respectively. The signals flowing in the memory test circuit 20c in each time section will be explained below. In a time section [T0, T1, T2, T3], since the memory test circuit 20c is in the test mode, the test signal test illustrated in FIG. 11B is set to “0”.

States of the respective signals in the time section [T0, T1] illustrated in FIG. 11B will be explained. During the period of [T0, T1], the signal nd21 output from the INVERTER circuit 21c, to which the read signal mout set to “0” is input, is “1” during the period of [T0, T1]. Although the expected value EXPD changes from “1” to “0” in T0, the signal nd24 output from the NAND circuit 22c-1, to which the expected value EXPD whose value is set to “0” and the test signal test whose value is set to “0” are input, has a value “1” during the period of [T0, T1]. Since the signal nd21 does not change from “1” during the period of [T0, T1], the signal nd22 output from the INVERTER circuit 22c-3, to which the signal nd21 is input, is “0” during the period of [T0, T1]. Since the signal nd4 does not change from “1” during the period of [T0, T1], the signal nd23 output from the INVERTER circuit 22c-2, to which the signal nd24 is input, is “0” during the period of [T0, T1].

As described above, since the signals nd21 to nd24 do not change during the period of [T0, T1], the signals output from the transfer gate circuits 22c-4 to 22c-6 of a rear stage do not change during the period of [T0, T1]. Accordingly, during the period of [T0, T1], the value of the signal nd25 is “1”, the value of the signal rdin is “0”, and the value of the signal RD is “0”.

A timing chart of a time section [T1, T2] illustrated in FIG. 11B will be explained. In the time section [T1, T2], the read signal mout is “1”.

When the read signal mout changes from “0” to “1” in T1, the signal nd21 output from the INVERTER circuit 21c, to which the read signal mout is input, changes from “1” to “0” in t321. The signal nd22 output from the INVERTER circuit 22c-3, to which the signal nd21 is input, changes from “0” to “1”. Further, the signal nd24 output from the NAND circuit 22c-1, to which the test signal test set to “0” and the expected value EXPD set to “0” are input, is “1” during the period of [T1, T2]. The signal nd23 output from the INVERTER circuit 22c-2, to which the signal nd24 set to “1” is input, is “0” during the period of [T1, T2].

In the transfer gate circuit 22c-4, since the signal nd24 input to the gate of the p-channel transistor is “1” as well as the signal nd23 input to the gate of the n-channel transistor is “0”, the transfer gate circuit 22c-4 is placed in the non-conductive state. In contrast, in the transfer gate circuit 22c-5, since the signal nd23 input to the gate of the p-channel transistor is “0” and the signal nd24 input to the gate of the n-channel transistor is “1”, the transfer gate circuit 22c-5 is placed in the conductive state.

In the transfer gate circuit 22c-5 in the conductive state, when the signal nd21 input to the source terminal is “0”, the signal nd25 output from the drain terminal changes from “1” to “0” in t322. Further, the INVERTER circuit 22c-6, to which the signal nd25 set to “0” is input, outputs the signal rdin, which changes from “0” to “1”, in t323. The signal rdin is input to the output latch circuit 17 and fixed in the next cycles [T2, T3], and the signal RD whose value is “1” is output from the output latch circuit 17.

A timing chart of a time section [T2, T3] illustrated in FIG. 11B will be explained. During the period of [T2, T3], the signal nd21 output from the INVERTER circuit 21c, to which the read signal mout set to “1” is input, is “0” during the period of [T2, T3]. Although the expected value EXPD changes from “0” to “1” in T2, the value of the signal nd24 output from the NAND circuit 22c-1, to which the expected value EXPD set to “1” and the test signal test set “0” are input, is “1” during the period of [T2, T3]. Since the signal nd21 does not change from “0” during the period of [T2, T3], the signal nd22 output from the INVERTER circuit 22c-3, to which the signal nd21 is input, is “1” during the period of [T2, T3]. Since the signal nd24 does not change from “1” during the period of [T2, T3], the signal nd23 output from the INVERTER circuit 22c-2, to which the signal nd24 is input, is “0” during the period of [T2, T3].

As described above, since the signals nd21 to nd24 do not change during the period of [T2, T3], the signals output from the transfer gate circuits 22c-4 to 22c-6 of a rear stage do not change during the period of [T0, T1]. Accordingly, during the period of [T2, T3], the value of the signal nd25 is “0”, the value of the signal rdin is “1”, and the value of the signal RD is “1”.

A timing chart of a time section [T3, T4] illustrated in FIG. 11B will be explained. When the read signal mout changes from “1” to “0” in T3, the signal nd21 output from the INVERTER circuit 21c, to which the read signal mout is input, changes from “0” to “1” in t324. The signal nd22 output from the INVERTER circuit 22c-3, to which the signal nd21 is input, changes from “1” to “0”. Further, the signal nd24 output from the NAND circuit 22c-1, to which the test signal test set to “0” and the expected value EXPD set to “1” are input, is “1” during the period of [T3, T4]. The signal nd23 output from the INVERTER circuit 22c-2, to which the signal nd24 set to “1” is input, is “0” during the period of [T3, T4].

In the transfer gate circuit 22c-4, since the signal nd24 input from the gate of the p-channel transistor is “1” as well as the signal nd23 input from the gate of the n-channel transistor is “0”, the transfer gate circuit 22c-4 is placed in the non-conductive state. In contrast, in the transfer gate circuit 22b-5, since the signal nd23 input from the gate of the p-channel transistor is “0” as well as the signal nd24 input from the gate of the n-channel transistor is “1”, the transfer gate circuit 22c-5 is placed in the conductive state.

When the signal nd21, which is input from the source terminal of the transfer gate circuit 22c-5 in the conductive state is set to “1”, the signal nd25 output from the drain terminal changes from “0” to “1” at t325. Further, the INVERTER circuit 22c-6, to which the signal nd25 is input, outputs the signal rdin, which is obtained by inverting the value “1” of the signal nd25 to “0” in t326. The signal rdin is input to the output latch circuit 17 and fixed in the next cycles [T4, T5], and the signal RD whose value is “0” is output from the output latch circuit 17.

As described above, when the test signal test has a logic value of “0”, the memory test circuit 20c can output the value of the read signal mout as it is.

Note that, although the NAND circuits 22a-4 and 22a-5 of the memory test circuit 20a are designed by circuits having two-stage gates as illustrated in FIG. 6B, the transfer gate circuits of the memory test circuits 20b, 20c are designed by circuits having one-stage gates. As a result, since a gate-pass time of the memory test circuits 20b, 20C is shorter than that of the memory test circuit 20a, a delay time of the memory test circuits 20b, 20c can be more reduced than that of the memory test circuit 20a.

The embodiments can be implemented in computing hardware (computing apparatus) and/or software, such as (in a non-limiting example) any computer that can store, retrieve, process and/or output data and/or communicate with other computers. The results produced can be displayed on a display of the computing hardware. A program/software implementing the embodiments may be recorded on computer-readable media comprising computer-readable recording media. The program/software implementing the embodiments may also be transmitted over transmission communication media. Examples of the computer-readable recording media include a magnetic recording apparatus, an optical disk, a magneto-optical disk, and/or a semiconductor memory (for example, RAM, ROM, etc.). Examples of the magnetic recording apparatus include a hard disk device (HDD), a flexible disk (FD), and a magnetic tape (MT). Examples of the optical disk include a DVD (Digital Versatile Disc), a DVD-RAM, a CD-ROM (Compact Disc-Read Only Memory), and a CD-R (Recordable)/RW. An example of communication media includes a carrier-wave signal.

Further, according to an aspect of the embodiments, any combinations of the described features, functions and/or operations can be provided.

The many features and advantages of the embodiments are apparent from the detailed specification and, thus, it is intended by the appended claims to cover all such features and advantages of the embodiments that fall within the true spirit and scope thereof. Further, since numerous modifications and changes will readily occur to those skilled in the art, it is not desired to limit the inventive embodiments to the exact construction and operation illustrated and described, and accordingly all suitable modifications and equivalents may be resorted to, falling within the scope thereof.

What is claimed is:

1. A memory test circuit for testing a memory, comprising:
a first circuit performing a logic operation of a test signal, which determines whether the memory is operated in a test mode or in an ordinary operation mode, and an expected value representing a value that is expected to be set to data read from the memory;
a second circuit outputting an exclusive OR of an output signal from the first circuit and the data read from the memory.

2. The memory test circuit according to claim 1, wherein the second circuit includes at least one transfer gate circuit inputting the read data to a control terminal or to a source terminal.

3. The memory test circuit according to claim 2, wherein the second circuit includes two transfer gate circuits, and when the memory is in the ordinary operation mode, no current flows to a control terminal of one of the transfer gate circuits by determining that the test signal has a negative logic.

4. A processor, comprising:
a memory;
an instruction unit outputting a first instruction signal instructing to read data from the memory in synchronization with a system clock signal;
a test signal creation unit outputting a second instruction signal instructing a test of the memory and an expected value representing a value that is expected to be set to data read from the memory in synchronization with the system clock signal;
a test signal output unit outputting a test signal for determining whether the memory is operated in a test mode or in an ordinary operation mode;
a first circuit performing a logic operation of the test signal and the expected value; and
a second circuit outputting an exclusive OR of a signal output from the first circuit and read data read from the memory.

5. A processor according to claim 4, wherein the second circuit includes at least one transfer gate inputting the read data to a control terminal or to a source terminal.

6. A processor according to claim 5, wherein the second circuit includes two transfer gate circuits, and when the memory is in the ordinary operation mode, no current flows to a control terminal of one of the transfer gate circuits by determining that the test signal has a negative logic.

7. A method for testing a memory, comprising:
performing a logic operation of a test signal, which determines whether the memory is operated in a test mode or in an ordinary operation mode, and an expected value representing a value that is expected to be set to data read from the memory;
outputting an exclusive OR of an output signal from the logic operation and the data read from the memory.
